(19) United States
(12) Patent Application Publication
(10) Pub. No.: US 2013/0328200 A1
(43) Pub. Date: Dec. 12, 2013

(54) DIRECT BONDED COPPER SUBSTRATE AND POWER SEMICONDUCTOR MODULE

(71) Applicant: Electronics and Telecommunications Research Institute, (US)

(72) Inventor: Hyun Cheol Bae, Daejeon (KR)

(73) Assignee: Electronics and Telecommunications Research Institute, Daejeon (KR)

(21) Appl. No.: 13/858,290

(22) Filed: Apr. 8, 2013

(30) Foreign Application Priority Data
Jun. 12, 2012 (KR) 10-2012-0062663

(51) Int. Cl. H01L 23/48

(52) U.S. Cl. CPC H01L 23/481
USPC 257/762

(57) ABSTRACT

Disclosed are a DBC substrate and a power semiconductor module having improved thermal reliability by directly forming a via in a substrate of a semiconductor device used mainly as a power device such as a silicon device, a silicon carbide (SiC) device, and a gallium nitride (GaN) device. The power semiconductor module includes: a DBC substrate including a ceramic base material defining a via, a lower copper layer connected to a bottom surface of the ceramic base material, and an upper copper layer connected to a top surface of the ceramic base material; a power semiconductor device stacked on the upper copper layer of the DBC substrate; and a heat dissipating device connected to the lower copper layer of the DBC substrate, and dissipating heat, generated by the operation of the power semiconductor device, through the via.

### CROSS-REFERENCE TO RELATED APPLICATIONS

This application is based on and claims priority from Korean Patent Application No. 10-2012-0062663, filed on Jun. 12, 2012, with the Korean Intellectual Property Office, the disclosure of which is incorporated herein in its entirety by reference.

### TECHNICAL FIELD

The present disclosure relates to a direct bonded copper (DBC) substrate and a power semiconductor module, and more particularly, to a DBC substrate and a power semiconductor module having improved thermal reliability by directly forming a via through a substrate of a semiconductor device used mainly as a power device such as a silicon device, a silicon carbide (SiC) device, and a gallium nitride (GaN) device.

### BACKGROUND

At present, power semiconductor modules use silicon power devices (IGBTs and the like), are applied to many areas in home appliances, automobiles, etc., and have increasing demand. At the same time, there is an increasing rise in the required power characteristics of a power semiconductor module. For a power semiconductor module for several hundred watts, a silicon carbide (SiC) device and a gallium nitride (GaN) device which have a wider bandgap than a silicon device are more suitable.

The most pressing issue in such power semiconductor device packages is how to effectively dissipate heat. This issue has the greatest effect on reliability due to an increase in power characteristics and excessive heat generation of a power module. Accordingly, in current power semiconductor packages, copper substrates or direct bonded copper (DBC) type substrates which have good thermal characteristics are applied, and a heat pipe or a heat spreader is installed on the rear surface of two substrates in order to lower the high level of heat generated by a power semiconductor.

While such substrates with good thermal characteristics are used, an advance of the power semiconductor modules require a greater breakdown voltages. As the power characteristic requirements become greater, securing thermal reliability in a power semiconductor device package becomes the greatest obstacle to overcome.

Thus, a technology is required for more efficiently dissipating heat.

### SUMMARY

The present disclosure has been made in an effort to provide a DBC substrate and a power semiconductor module having improved heat dissipating characteristics, by forming a via in a DBC (direct bonded copper) substrate, filling the formed via with copper, and connecting a heat pipe or a heat spreader to the rear surface of the DBC substrate through the via.

An exemplary embodiment of the present disclosure provides a direct bonded copper (DBC) substrate including: a ceramic base material defining a via; a lower copper layer connected to a bottom surface of the ceramic base material; and an upper copper layer connected to a top surface of the ceramic base material to have a pattern.

The ceramic base material may be alumina (Al₂O₃) or aluminum nitride (AlN).

Another exemplary embodiment of the present disclosure provides a power semiconductor module including: a DBC substrate including a ceramic base material defining a via, a lower copper layer connected to a bottom surface of the ceramic base material, and an upper copper layer connected to a top surface of the ceramic base material; a power semiconductor element stacked on the upper copper layer of the DB C substrate; and a heat dissipating element connected to the lower copper layer of the DBC substrate, and dissipating heat, generated by the operation of the power semiconductor element, through the via.

The heat dissipating element may include a heat pipe or a heat spreader.

The power semiconductor element may be electrically connected to a pad through wire bonding.

The power semiconductor module may further include: an additional DBC substrate having the same structure as the DBC substrate; and an additional heat dissipating element connected to a lower copper layer of the additional DBC substrate, and dissipating heat generated by the operation of the power semiconductor element, in which the additional DBC substrate and the additional heat dissipating element may be formed of a structure symmetrical to the DBC substrate and the heat dissipating element, with respect to the power semiconductor element.

The power semiconductor element may be electrically connected to a pad through a sintering process.

According to the exemplary embodiments of the present disclosure, a via is formed in a ceramic base material of a DBC substrate, filled with copper, and connected to a heat dissipating element such as a heat pipe or a heat spreader, so as to improve heat dissipating characteristics.

According to the exemplary embodiments of the present disclosure, the DBC substrate in which the via is formed is formed in multiple layers, so as to increase heat dissipating effects.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a drawing illustrating a conventional structure of a DBC substrate applied to an exemplary embodiment of the present disclosure.

FIG. 2 is a drawing illustrating a conventional structure of a power semiconductor module including a DBC substrate applied to an exemplary embodiment of the present disclosure.

FIG. 3 is a drawing illustrating a structure of a DBC substrate having a via according to an exemplary embodiment of the present disclosure.

FIG. 4 is a drawing illustrating a structure of a power semiconductor module including a DBC substrate having a via according to an exemplary embodiment of the present disclosure.

FIG. 5 is a drawing illustrating a power semiconductor module including a multilayer DBC substrate according to another exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

A direct bonded copper (DBC) substrate used in an exemplary embodiment of the present disclosure is advantageous in not only having higher heat dissipating characteristics than it of a case where a lead is disposed over a conventional heat dissipating device, but in being able to provide a semiconductor power module with improved reliability, productivity, and consistency because an inspection process for the bonded state of a heat dissipating plate is not needed. When the DBC substrate is used, a semiconductor may be directly mounted over a circuit, in order to provide a semiconductor mounted substrate with good heat dissipation.

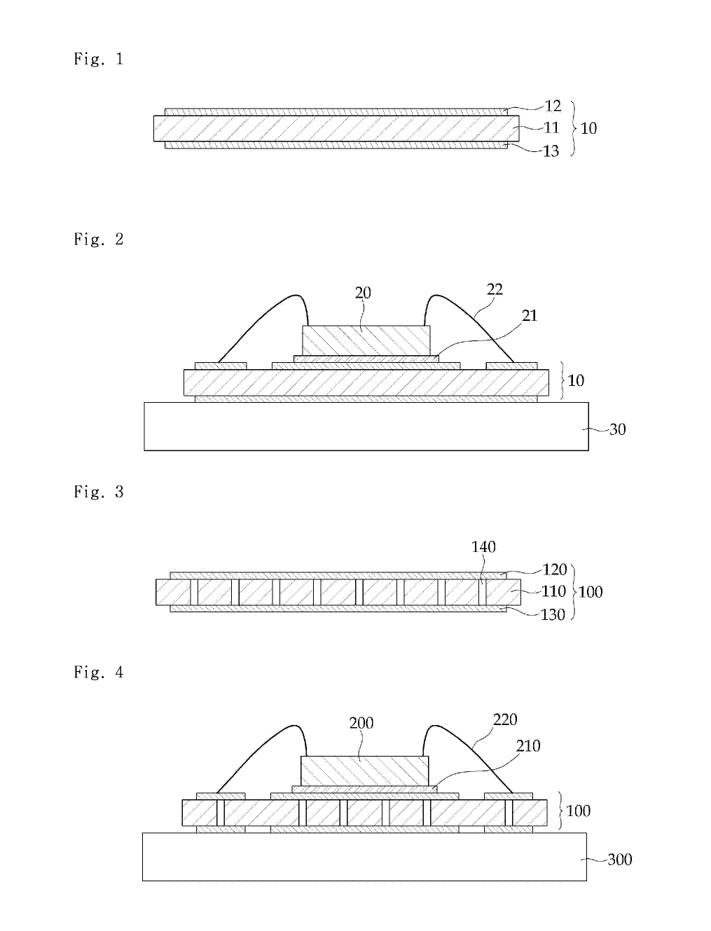

A conventional structure of a DBC (direct bonded copper) substrate as illustrated in FIG. 1 is a bonded structure of a ceramic base material 11 of alumina (Al₂O₃) or aluminum nitride (AlN) which is an insulating material, a lower copper layer 13 connected to a bottom surface of the ceramic base material 11, and an upper copper layer 12 connected to a top surface of the ceramic base material 11 to have a pattern. Both sides of the DBC substrate 10 are bonded with copper and can be soldered or wire bonded.

FIG. 2 illustrates a power semiconductor module in which a power semiconductor device 20 is attached over a DBC substrate 10 through a die bonding process with an adhesive 21, and the power semiconductor device 20 and a pad are electrically connected through a wire bonding 22. In this case, a heat dissipating device 30 such as a heat pipe or a heat spreader is attached through a soldering bonding method to the rear surface of the DBC substrate 10, so as to dissipate heat generated by the operation of the power semiconductor device 20.

FIG. 3 is a drawing illustrating a structure of a DBC substrate 100 having a via according to an exemplary embodiment of the present disclosure.

Referring to FIG. 3, a DBC substrate 100 having a via 140 includes a ceramic base material 110 defining a via, a lower copper layer 130 connected to a bottom surface of the ceramic base material 110, and an upper copper layer 120 connected to a top surface of the ceramic base material 110 to have a pattern.

The ceramic base material 110 is formed of alumina (Al₂O₃) or aluminum nitride (AlN), for example. The via 140 is filled with copper.

FIG. 4 is a drawing illustrating a structure of a power semiconductor module including a DBC substrate having a via according to an exemplary embodiment of the present disclosure.

Referring to FIG. 4, the power semiconductor module includes a DBC substrate 100 defining a via 140, a power semiconductor device 200, and a heat dissipating device 300.

The DBC substrate 100 is a structure including a ceramic base material, a lower copper layer connected to a bottom surface of the ceramic base material, and an upper copper layer connected to a top surface of the ceramic base material.

The power semiconductor device 200 is stacked through a soldering process on the upper copper layer of the DBC substrate 100.

The heat dissipating device 300 is connected to the lower copper layer of the DBC substrate 100, so as to dissipate heat generated by the operation of the power semiconductor device 200 and transferred through the via 140. The heat dissipating device 300 may be a heat pipe and a heat spreader, for example.

In this structure, because the heat generated from the power semiconductor device 200 with high power characteristics is connected to a heat dissipating device such as a heat pipe or a heat spreader through the via 140 of the DBC substrate 100, the heat dissipating characteristics may be improved. When heat dissipation is efficiently performed, the power characteristics of the power semiconductor module are improved, and improved characteristics for reliability may also be obtained.

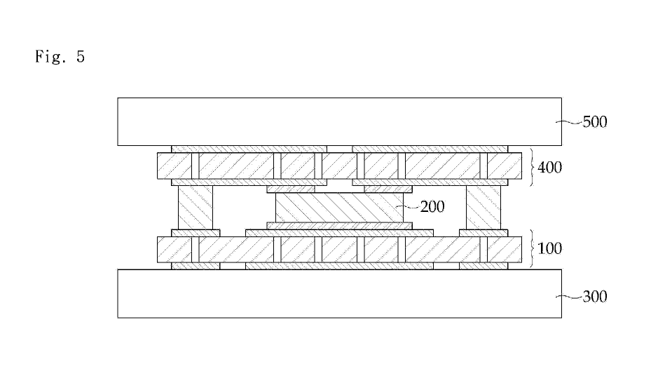

FIG. 5 is a drawing illustrating a power semiconductor module including a multilayer DBC substrate according to another exemplary embodiment of the present disclosure.

Referring to FIG. 5, a multilayer DBC substrate may be included, which has a first DBC substrate 100 and a second DBC substrate 400 symmetrically connected with respect to a power semiconductor device.

The first DBC substrate 100 and the second DBC substrate 400 have heat dissipating devices 300 and 500 connected to surfaces thereof, respectively, on which the power semiconductor device is not connected.

The first DBC substrate 100 and the second DBC substrate 400 are structures including a ceramic base material defining a via, a lower copper layer connected to a bottom surface of the ceramic base material, and an upper copper layer connected to a top surface of the ceramic base material.

A power semiconductor device may be connected to the first DBC substrate 100 and the second DBC substrate 400 through die bonding.

In the case of a power semiconductor module having such a multilayer DBC substrate, the method of connecting a power semiconductor device and a pad uses a sintering process that uses soldering or nano powder. In this case, heat generated by the operation of the power semiconductor device 200 is dissipated by the heat dissipating devices 300 and 500 at both sides through vias at the top and bottom, so that the heat dissipating effect may be further improved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A direct bonded copper (DBC) substrate comprising:
a ceramic base material defining a via;
a lower copper layer connected to a bottom surface of the ceramic base material; and
an upper copper layer connected to a top surface of the ceramic base material to have a pattern.

2. The DBC substrate of claim 1, wherein the ceramic base material is alumina (Al₂O₃) or aluminum nitride (AlN).

3. The DBC substrate of claim 1, wherein the via is filled with copper.

4. A power semiconductor module comprising:
a direct bonded copper (DBC) substrate including a ceramic base material defining a via, a lower copper layer connected to a bottom surface of the ceramic base material, and an upper copper layer connected to a top surface of the ceramic base material;
a power semiconductor element stacked on the upper copper layer of the DBC substrate; and
a heat dissipating element connected to the lower copper layer of the DBC substrate, and configured to dissipate heat, generated by the operation of the power semiconductor element, through the via.

5. The power semiconductor module of claim 4, wherein the heat dissipating element includes a heat pipe or a heat spreader.

6. The power semiconductor module of claim 4, wherein the power semiconductor element is electrically connected to a pad through wire bonding.

7. The power semiconductor module of claim 4, further comprising:
an additional DBC substrate having the same structure as the DBC substrate; and
an additional heat dissipating element connected to a lower copper layer of the additional DBC substrate, and configured to dissipate heat generated by the operation of the power semiconductor element,
wherein the additional DBC substrate and the additional heat dissipating element are formed of a structure symmetrical to the DBC substrate and the heat dissipating element, with respect to the power semiconductor element.

8. The power semiconductor module of claim 7, wherein the power semiconductor element is electrically connected to a pad through a sintering process.
